(19) United States
(12) Patent Application Publication
(10) Pub. No.: US 2011/0199162 A1
(43) Pub. Date: Aug. 18, 2011

(54) PACKAGE, METHOD OF MANUFACTURING THE SAME, PIEZOELECTRIC VIBRATOR, OSCILLATOR, ELECTRONIC APPARATUS, AND RADIO-CONTROLLED TIMEPIECE

(76) Inventor: Yoichi Funabiki, Chiba-shi (JP)

(21) Appl. No.: 13/029,540

(22) Filed: Feb. 17, 2011

(30) Foreign Application Priority Data
Feb. 18, 2010 (JP) 2010-033928

(51) Int. Cl. H01L 41/053; B32B 37/02; B32B 37/12; B32B 37/14; B32B 37/10; B32B 38/10; H05K 13/00; H03B 5/32

(52) U.S. Cl. 331/158; 156/250; 156/251; 310/344

(57) ABSTRACT

Provided are a package and a method of manufacturing the package capable of suppressing corrosion of a bonding material and providing excellent airtightness, and to provide a piezoelectric vibrator, an oscillator, an electronic apparatus, and a radio-controlled timepiece. A bonding material formed on a front surface of a base substrate is anodically bonded to a frame region of a lid substrate. On the outer surface of a package, a protection film made of a material having higher resistance to corrosion than the bonding material is formed so as to cover at least the bonding material exposed between the base substrate and the lid substrate.

### RELATED APPLICATIONS

This application claims priority under 35 U.S.C. §119 to Japanese Patent Application No. 2010-033928 filed on Feb. 18, 2010, the entire content of which is hereby incorporated by reference.

### FIELD OF THE INVENTION

The present invention relates to a package, a method of manufacturing the package, a piezoelectric vibrator, and an oscillator, an electronic apparatus, and a radio-controlled timepiece each having the piezoelectric vibrator.

### BACKGROUND ART

Recently, a piezoelectric vibrator utilizing quartz or the like has been used in cellular phones and portable information terminals as the time source, the timing source of a control signal, a reference signal source, and the like. The piezoelectric vibrator of this type is proposed in a variety of forms, and a surface mounted device-type piezoelectric vibrator is one example. The piezoelectric vibrator of this type includes, for example, a base substrate and a lid substrate which are bonded to each other and are made of a glass material, a cavity formed between the two substrates, and a piezoelectric vibrating reed (electronic component) accommodated in a state of being airtightly sealed in the cavity.

As a method of directly bonding the base substrate and the lid substrate, anodic bonding is proposed. Anodic bonding is a method that involves applying a voltage between a bonding material formed on the inner surface of one of a base substrate and a lid substrate and the other substrate to bond the bonding material to the inner surface of the other substrate. As a material of the bonding material, aluminum (Al) having a relatively low resistance may be used. In this way, by using Al for the bonding material, it is expected that a voltage can be applied to the entire surface of the bonding material in a uniform manner and the bonding material and the inner surface of the other surface can be reliably anodically bonded. Moreover, JP-A-2006-339840 discloses a configuration in which an Al alloy containing copper (Cu) in addition to Al is used as the bonding material in order to increase the voltage resistance of the bonding material.

However, since Al is a material having a low resistance to corrosion (relatively high ionization tendency), when the bonding material made of Al is exposed from the outer surface of the piezoelectric vibrator, there is a problem in that the bonding material is easily corroded.

Particularly, when moisture adheres to the bonding material, Al on the surface is deprived of electrons and ionized (disassociated) due to a redox reaction of Al and moisture. Thus, the generated Al ions react with hydroxide (OH) ions in the moisture to leak as aluminum hydroxide (Al(OH₃)). When this reaction proceeds to the inner side of the bonding material, there is a possibility that the inside of the cavity communicates with the outside and the airtightness (gas barrier property of the bonding material) of the piezoelectric vibrator is deteriorated. That is, when the air enters into the cavity through the communicated portions, there is a problem in that the vibration properties of the piezoelectric vibrating reed are deteriorated. The same problem may occur when the Al alloy containing Cu in addition to Al is used for the bonding material similarly to JP-A-2006-339840.

### SUMMARY OF THE INVENTION

The present invention has been made in view of the above problems, and an object of the present invention is to provide a package and a method of manufacturing the package capable of suppressing corrosion of a bonding material and providing excellent airtightness, and to provide a piezoelectric vibrator, an oscillator, an electronic apparatus, and a radio-controlled timepiece.

In order to solve the problems, the invention provides the following means.

According to an aspect of the present invention, there is provided a package which includes a first substrate and a second substrate bonded to each other, each of the first and second substrates being made of an insulator, and a cavity formed between the first and second substrates, and which is capable of sealing an electronic component in the cavity. A bonding material formed on a bonding surface of the first substrate is anodically bonded to a bonding surface of the second substrate. On an outer surface of the package, a protection film made of a material having higher resistance to corrosion than the bonding material is formed so as to cover at least the bonding material exposed between the first and second substrates.

According to this configuration, since the bonding material is covered by the protection film, the bonding material will not be exposed to the outside. Therefore, it is possible to suppress the bonding material from coming into contact with the air and to suppress corrosion of the bonding material due to moisture or the like in the air. In this case, since the protection film is formed of a material having higher resistance to corrosion than the bonding material, it is possible to suppress the bonding material from being exposed to the outside due to corrosion of the protection film. Therefore, it is possible to reliably suppress the corrosion of the bonding material and to maintain the airtightness of the cavity for a long period.

The first and second substrates may be formed of a glass material, and the protection film may be formed from Si or Cr.

According to this configuration, it is possible to improve adhesion between the first and second substrates and the protection film and to suppress a gap from being formed between the respective substrates and the protection film or separation of the protection film. Therefore, it is possible to reliably maintain the airtightness of the cavity.

On the outer surface of the package, a pair of outer electrodes may be formed so as to be separated from the protection film.

According to this configuration, even when a conductive material is used for the protection film, since the outer electrodes are not bridged by the protection film, it is possible to prevent short-circuiting of the outer electrodes.

On the outer surface of the package, a marking is printed by removing a part of the protection film.

According to this configuration, since it is not necessary to form an additional plating film or the like in order to print the marking, it is possible to improve manufacturing efficiency.

According to another aspect of the present invention, there is provided a method of manufacturing a package which includes a cavity configured to be capable of sealing an electronic component between a first substrate and a second substrate bonded to each other, each of the first and second substrates being made of an insulator. The package manufacturing method includes a bonding step of anodically bonding a bonding material formed on a bonding surface of the first substrate to a bonding surface of the second surface; and a protection film forming step of forming a protection film made of a material having higher resistance to corrosion than the bonding material so as to cover at least the bonding material exposed between the first and second substrates on an outer surface of the package.

According to this configuration, since in the protection film forming step, the bonding material is covered by the protection film, the bonding material will not be exposed to the outside. Therefore, it is possible to suppress the bonding material from coming into contact with the air and to suppress corrosion of the bonding material due to moisture or the like in the air. In this case, since the protection film is formed of a material having higher resistance to corrosion than the bonding material, it is possible to suppress the bonding material from being exposed to the outside due to corrosion of the protection film. Therefore, it is possible to reliably suppress the corrosion of the bonding material and to maintain the airtightness of the cavity for a long period.

In the bonding step, a plurality of first substrates included in a first wafer and a plurality of second substrates included in a second wafer may be anodically bonded. The package manufacturing method may include, between the bonding step and the protection film forming step, a step of attaching an adhesive sheet to one surface of an assembled body of the first and second wafers; a fragmentation step of fragmenting the assembled body for each formation region of the package to form a plurality of assembled fragments; and an expanding step of expanding the adhesive sheet to widen the space between the fragmented assembled fragments. In the protection film forming step, the protection film may be formed from the other surface side of the plurality of assembled fragments in a state where the plurality of assembled fragments is disposed so as to be separated from each other on the expanded adhesive sheet.

Since the bonding material is exposed to the outer surface of the assembled fragment, in order to form the protection film so as to cover the bonding material, it is necessary to dispose all assembled fragments so as to be separated from each other so that the outer surfaces are exposed.

According to the configuration of the present invention, since the protection film forming step is performed in a state where the plurality of assembled fragments are separated from each other in the expanding step, it is not necessary to dispose all assembled fragments again so as to be spaced from each other, and thus, manufacturing efficiency can be improved. That is, since the protection film can be formed in a state where a space is secured between the respective assembled fragments, it is possible to form the protection film in a uniform manner with respect to the bonding material exposed between the first and second substrates in the respective assembled fragments.

Moreover, since the protection film can be formed at a time with respect to the plurality of fragmented assembled fragments, it is possible to improve manufacturing efficiency as compared to the case of forming the protection films on the assembled fragments one by one. Moreover, by forming the protection film in a state where the respective assembled fragments are attached to the adhesive sheet, it is possible to suppress the movement of the assembled fragments at the time of transferring to the deposition machine or deposition.

At a later stage of the protection film forming step, the package manufacturing method may include a marking step of irradiating a laser beam to the protection film formed on the other surface of the assembled fragment to remove a part of the protection film, thus printing a marking.

According to this configuration, since it is not necessary to form an additional plating film or the like in order to print the marking, it is possible to improve manufacturing efficiency.

According to a further aspect of the present invention, there is provided a piezoelectric vibrator in which a piezoelectric vibrating reed is airtightly sealed in the cavity of the package according to the above aspect of the present invention.

According to this configuration, since the piezoelectric vibrator includes the package having excellent airtightness, it is possible to provide a piezoelectric vibrator having excellent vibration characteristics and high reliability.

According to still another aspect of the invention, there is provided an oscillator in which the above-described piezoelectric vibrator is electrically connected to an integrated circuit as an oscillating piece.

According to still another aspect of the invention, there is provided an electronic apparatus in which the above-described piezoelectric vibrator is electrically connected to a clock section.

According to still another aspect of the invention, there is provided a radio-controlled timepiece in which the above-described piezoelectric vibrator is electrically connected to a filter section.

Since each of the oscillator, electronic apparatus, and radio-controlled timepiece of the above aspects of the present invention includes the piezoelectric vibrator having excellent vibration characteristics and high reliability, an oscillator, an electronic apparatus, and a radio-controlled timepiece having excellent characteristics and reliability can be provided similarly to the piezoelectric vibrator.

According to the package and the package manufacturing method according to the above aspect of the present invention, it is possible to prevent corrosion of the bonding material and to provide a package having excellent airtightness.

According to the piezoelectric vibrator according to the above aspect of the present invention, it is possible to maintain the airtightness of the cavity and to provide a piezoelectric vibrator having excellent vibration characteristics and high reliability.

According to the oscillator, electronic apparatus, and radio-controlled timepiece according to the above aspect of the present invention, since they include the piezoelectric vibrator according to the above aspect of the present invention, it is possible to provide products having excellent characteristics and reliability similarly to the piezoelectric vibrator.

### BRIEF DESCRIPTION OF THE DRAWINGS

FIG. 1 is a perspective view showing an external appearance of a piezoelectric vibrator according to an embodiment of the present invention as seen from the side of a lid substrate.

FIG. 2 is a perspective view showing an external appearance of the piezoelectric vibrator according to an embodiment of the present invention as seen from the side of a base substrate.

FIG. 3 is a top view showing an inner structure of the piezoelectric vibrator, showing a state where the lid substrate is removed.

FIG. 4 is a sectional view of the piezoelectric vibrator taken along the line A-A in FIG. 3.

FIG. 5 is an exploded perspective view of the piezoelectric vibrator shown in FIG. 1.

FIG. 6 is a flowchart showing the flow of the manufacturing process of the piezoelectric vibrator shown in FIG. 1.

FIG. 7 is a diagram showing one step of the manufacturing process of the piezoelectric vibrator in accordance with the flowchart shown in FIG. 6 and is an exploded perspective view showing a wafer assembly in which a base substrate wafer and a lid substrate wafer are anodically bonded with the piezoelectric vibrating reed accommodated in a cavity.

FIG. 8 is a sectional view illustrating a fragmentation step, showing a state where the wafer assembly is held on a magazine.

FIG. 9 is a sectional view illustrating the fragmentation step, showing a state where the wafer assembly is held on the magazine.

FIG. 10 is a sectional view illustrating the fragmentation step, showing a state where the wafer assembly is held on the magazine.

FIG. 11 is a sectional view illustrating the fragmentation step, showing a state where the wafer assembly is held on a magazine.

FIG. 12 is a sectional view illustrating the fragmentation step, showing a state where the wafer assembly is held on the magazine.

FIG. 13 is a sectional view illustrating a protection film forming step, showing a state where a plurality of piezoelectric vibrators is attached to a UV tape.

FIG. 14 is a perspective view illustrating a marking step, showing an external appearance of the piezoelectric vibrator corresponding to FIG. 1.

FIG. 15 is a view showing the configuration of an oscillator according to an embodiment of the present invention.

FIG. 16 is a view showing the configuration of an electronic apparatus according to an embodiment of the present invention.

FIG. 17 is a view showing the configuration of a radio-controlled timepiece according to an embodiment of the present invention.

### DETAILED DESCRIPTION OF THE PREFERRED EMBODIMENTS

Hereinafter, an embodiment of the present invention will be described with reference to the drawings.

### Piezoelectric Vibrator

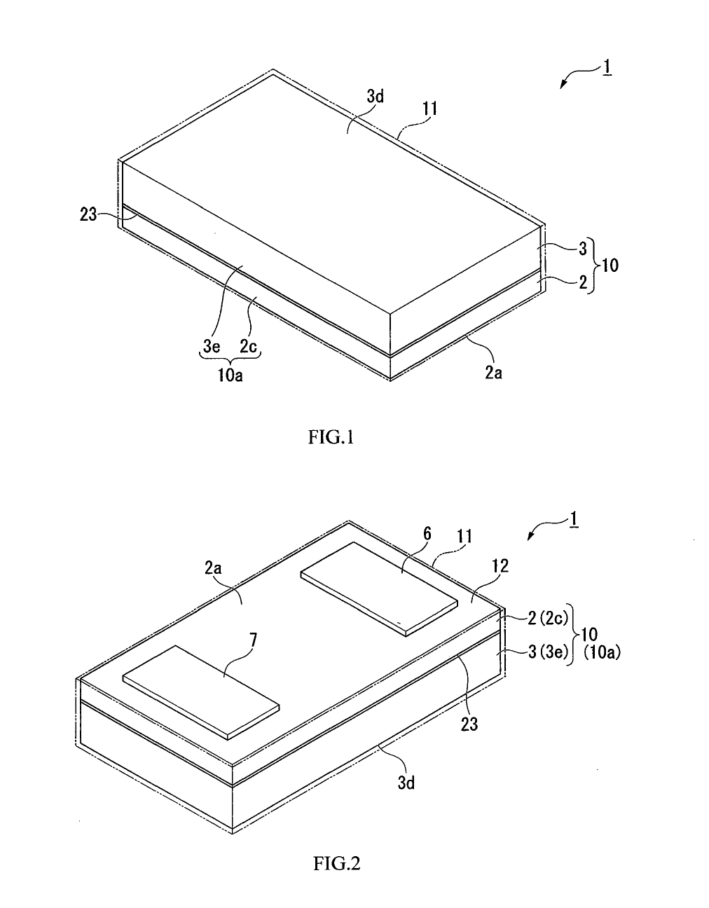

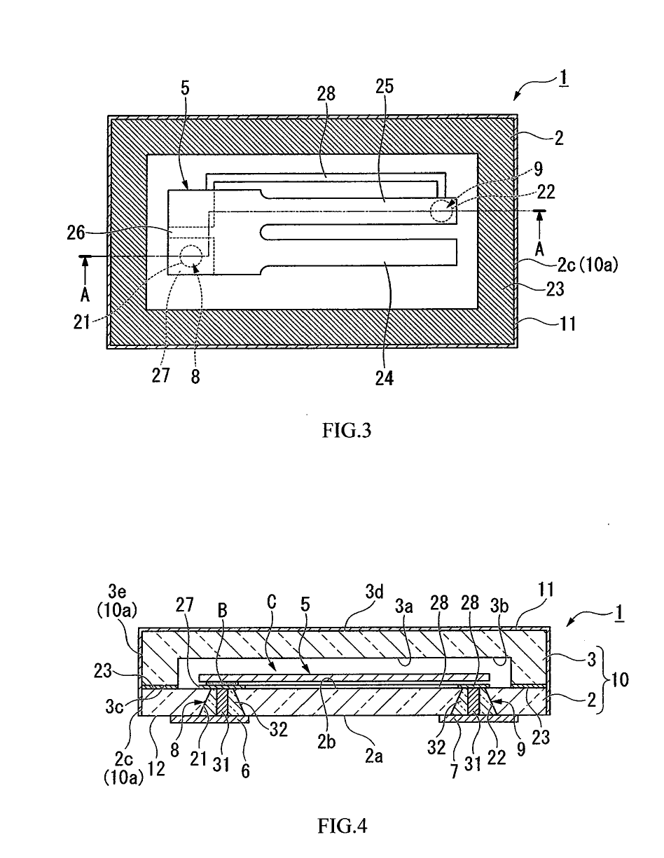

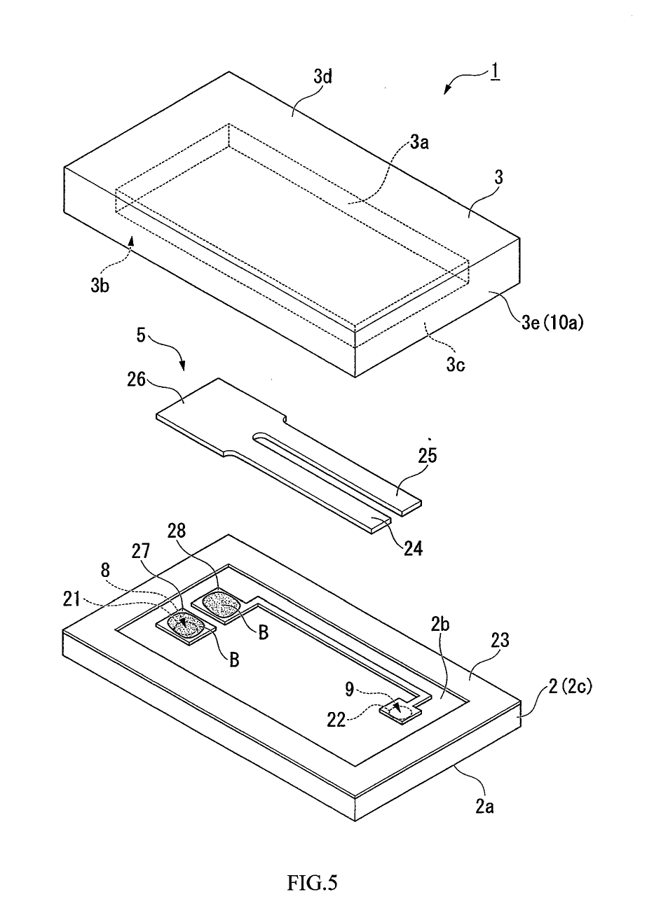

FIG. 1 is a perspective view showing an external appearance of a piezoelectric vibrator according to an embodiment of the present invention as seen from the side of a lid substrate. FIG. 2 is a perspective view showing an external appearance of the piezoelectric vibrator according to an embodiment of the present invention as seen from the side of a base substrate. FIG. 3 is a top view showing an inner structure of the piezoelectric vibrator, showing a state where the lid substrate is removed. FIG. 4 is a sectional view of the piezoelectric vibrator taken along the line A-A in FIG. 3. FIG. 5 is an exploded perspective view of the piezoelectric vibrator. In FIGS. 1 and 2, a protection film described later is depicted by a chain line.

As shown in FIGS. 1 to 5, a piezoelectric vibrator 1 of this embodiment is a surface mounted device-type piezoelectric vibrator 1 which includes a box-like package 10 in which a base substrate (first substrate) 2 and a lid substrate (second substrate) 3 are anodically bonded by a bonding material 23, and a piezoelectric vibrating reed (electronic component) 5 accommodated in a cavity C of the package 10. The piezoelectric vibrating reed 5 and outer electrodes 6 and 7 which are provided on a rear surface 2a (the lower surface in FIG. 4) of the base substrate 2 are electrically connected by a pair of penetration electrodes 8 and 9 penetrating through the base substrate 2.

The base substrate 2 is a transparent insulating substrate made of a glass material, for example, soda-lime glass, and is formed in a substrate-like form. The base substrate 2 is formed with a pair of through-holes 21 and 22 in which a pair of penetration electrodes 8 and 9 is formed. The through-holes 21 and 22 are formed in a tapered form in sectional view whose diameter gradually decreases from the rear surface 2a of the base substrate 2 towards the front surface 2b (the upper surface in FIG. 4).

The lid substrate 3 is a transparent insulating substrate made of glass material, for example, soda-lime glass, similarly to the base substrate 2, and is formed in a substrate-like form having a size capable of being superimposed on the base substrate 2. Moreover, a rectangular recess portion 3a in which the piezoelectric vibrating reed 5 is accommodated is formed on the rear surface 3b (the lower surface in FIG. 4) side of the lid substrate 3. The recess portion 3a forms a cavity C that accommodates the piezoelectric vibrating reed 5 when the base substrate 2 and the lid substrate 3 are superimposed on each other. Moreover, the lid substrate 3 is anodically bonded to the base substrate 2 with a bonding material 23 disposed therebetween in a state where the recess portion 3a faces the base substrate 2. That is, the recess portion 3a which is formed at the central portion and a frame region 3c which is formed around the recess portion 3a and serves as a bonding surface to be bonded to the base substrate 2 are formed on the rear surface 3b side of the lid substrate 3.

The piezoelectric vibrating reed 5 is a tuning-fork type vibrating reed which is made of a piezoelectric material such as quartz crystal, lithium tantalate, or lithium niobate and is configured to vibrate when a predetermined voltage is applied thereto.

The piezoelectric vibrating reed 5 is a tuning-fork piezoelectric vibrating reed which includes a pair of vibrating arms 24 and 25 disposed in parallel to each other and a base portion 26 to which the base end sides of the pair of vibrating arms 24 and 25 are integrally fixed. On the outer surfaces of the pair of vibrating arms 24 and 25, an excitation electrode which allows the pair of vibrating arms 24 and 25 to vibrate and includes a pair of first and second excitation electrodes (not shown); and a pair of mount electrodes (not shown) which electrically connects the first and second excitation electrodes to lead-out electrodes 27 and 28 described later are provided.

As shown in FIGS. 3 and 4, the piezoelectric vibrating reed 5 configured in this way is bump-bonded on the lead-out electrodes 27 and 28, which are formed on the front surface 2b of the base substrate 2, using bumps B made of gold or the like. More specifically, the first excitation electrode of the piezoelectric vibrating reed 5 is bump-bonded on one lead-out electrode 27 via one mount electrode and the bumps B, and the second excitation electrode is bump-bonded on the other lead-out electrode 28 via the other mount electrode and the bumps B. In this way, the piezoelectric vibrating reed 5 is supported in a state of being floated from the front surface 2b of the base substrate 2, and the respective mount electrodes and the lead-out electrodes 27 and 28 are electrically connected to each other.

A bonding material 23 for anodic bonding made of Al is formed on the front surface 2b side of the base substrate 2 (the bonding surface side to be bonded to the lid substrate 3). The bonding material 23 has a thickness of about 3000 Å to 5000 Å, for example, and is formed along the outer circumferential portion of the base substrate 2 so as to face the frame region 3c of the lid substrate 3. Moreover, the bonding material 23 and the frame region 3c of the lid substrate 3 are anodically bonded to each other, whereby the cavity C is vacuum-sealed. The side surfaces of the bonding material 23 are formed to be approximately flush with the side surfaces 2c and 3e (the side surface (outer side surface) 10a of the package 10) of the base substrate 2 and the lid substrate 3.

The outer electrodes 6 and 7 are provided on both sides in the longitudinal direction of the rear surface 2a of the base substrate 2 (the surface on the opposite side to the bonding surface of the base substrate 2) and are electrically connected to the piezoelectric vibrating reed 5 via the penetration electrodes 8 and 9 and the lead-out electrodes 27 and 28. More specifically, one outer electrode 6 is electrically connected to one mount electrode of the piezoelectric vibrating reed 5 via one penetration electrode 8 and one lead-out electrode 27. On the other hand, the other outer electrode 7 is electrically connected to the other mount electrode of the piezoelectric vibrating reed 5 via the other penetration electrode 9 and the other lead-out electrode 28. Moreover, the side surfaces (the outer circumferences) of the outer electrodes 6 and 7 are positioned further closer to the inner side than the side surfaces 2c of the base substrate 2.

The penetration electrodes 8 and 9 are formed by a cylindrical member 32 and a core portion 31 which are integrally fixed to the through-holes 21 and 22 by baking. The penetration electrodes 8 and 9 serve to maintain airtightness of the cavity C by completely blocking the through-holes 21 and 22 and achieve electrical connection between the outer electrodes 6 and 7 and the lead-out electrodes 27 and 28. Specifically, one penetration electrode 8 is disposed below the lead-out electrode 27 and between the outer electrode 6 and the base portion 26. The other penetration electrode 9 is disposed below the lead-out electrode 28 and between the outer electrode 7 and the vibrating arm 25.

The cylindrical member 32 is obtained by baking a paste-like glass frit. The cylindrical member 32 has a cylindrical shape of which both ends are flat and which has approximately the same thickness as the base substrate 2. The core portion 31 is disposed at the center of the cylindrical member 32 so as to penetrate through the central hole of the cylindrical member 32. In the present embodiment, the cylindrical member 32 has an approximately conical outer shape (a tapered sectional shape) so as to comply with the shapes of the through-holes 21 and 22. The cylindrical member 32 is baked in a state of being buried in the through-holes 21 and 22 and is tightly attached to the through-holes 21 and 22.

The core portion 31 is a conductive cylindrical core material made of metallic material, and similarly to the cylindrical member 32, has a shape which has flat ends and approximately the same thickness as the base substrate 2. The electrical connection of the penetration electrodes 8 and 8 is secured via the conductive core portion 31.

As shown in FIGS. 1 to 4, a protection film 11 is formed on the package 10 so as to cover the entire area including the front surface 3d of the lid substrate 3, the side surfaces 3e of the lid substrate 3, and the side surfaces 2c (the side surfaces 10a of the package 10) of the base substrate 2. The protection film 11 is made of a metal material, such as silicon (Si), chromium (Cr), or titanium (Ti), having higher resistance to corrosion (lower ionization tendency) than the bonding material 23. Among these metal materials, in the present embodiment, Si or Cr is suitably used. In this way, it is possible to improve adhesion between the protection film 11 and the base substrate 2 and the lid substrate 3 and to suppress a gap from being formed between the protection film 11 and the substrates 2 and 3 or separation of the protection film 11.

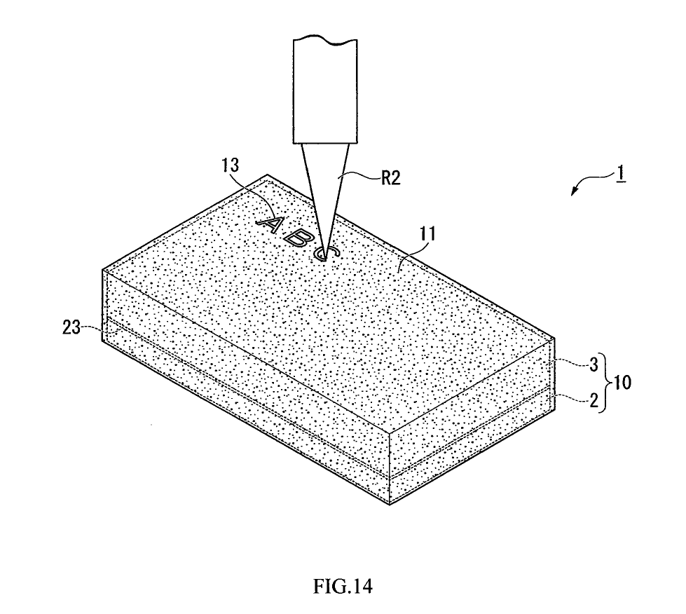

The protection film 11 is formed so as to have a thickness of about 1000 Å, for example, on the front surface 3d of the lid substrate 3 (the surface on the opposite side of the bonding surface of the lid substrate 3). Moreover, some of the protection film 11 is removed by a laser beam R2 (see FIG. 14), whereby a marking 13 such as a product type, a product number, or the date of manufacturing is printed on the front surface 3d of the lid substrate 3 (see FIG. 14). In order to print the marking 13, it is preferable to form the protection film 11 using Si having high absorption to the laser beam R2.

Moreover, the protection film 11 is formed so as to have a thickness of about 300 Å to 400 Å, for example, on the side surface 10a of the package 10 and to cover the bonding material 23 exposed to the outside between the base substrate 2 and the lid substrate 3. Moreover, the peripheral edge (the lower end in FIG. 4) of the protection film 11 is formed to be approximately flush with the rear surface 2a of the base substrate 2. That is, the protection film 11 is not formed on the rear surface 2a of the base substrate 2. In this case, as described above, since the side surfaces of the outer electrodes 6 and 7 are positioned further closer to the inner side than the side surfaces 2c of the base substrate 2, the peripheral edge of the protection film 11 and the outer electrodes 6 and 7 are disposed so as to be separated with a gap 12 therebetween. In this way, even when a conductive material is used for the protection film 11, since the outer electrodes 6 and 7 are not bridged by the protection film 11, it is possible to prevent short-circuiting of the outer electrodes 6 and 7.

When the piezoelectric vibrator 1 configured in this manner is operated, a predetermined drive voltage is applied between the pair of outer electrodes 6 and 7 formed on the base substrate 2. In this way, a current can be made to flow to the excitation electrodes of the piezoelectric vibrating reed 5, and the pair of vibrating arms 24 and 25 is allowed to vibrate at a predetermined frequency in a direction to move closer to or away from each other. This vibration of the pair of vibrating arms 24 and 25 can be used as the time source, the timing source of a control signal, the reference signal source, and the like.

### Piezoelectric Vibrator Manufacturing Method

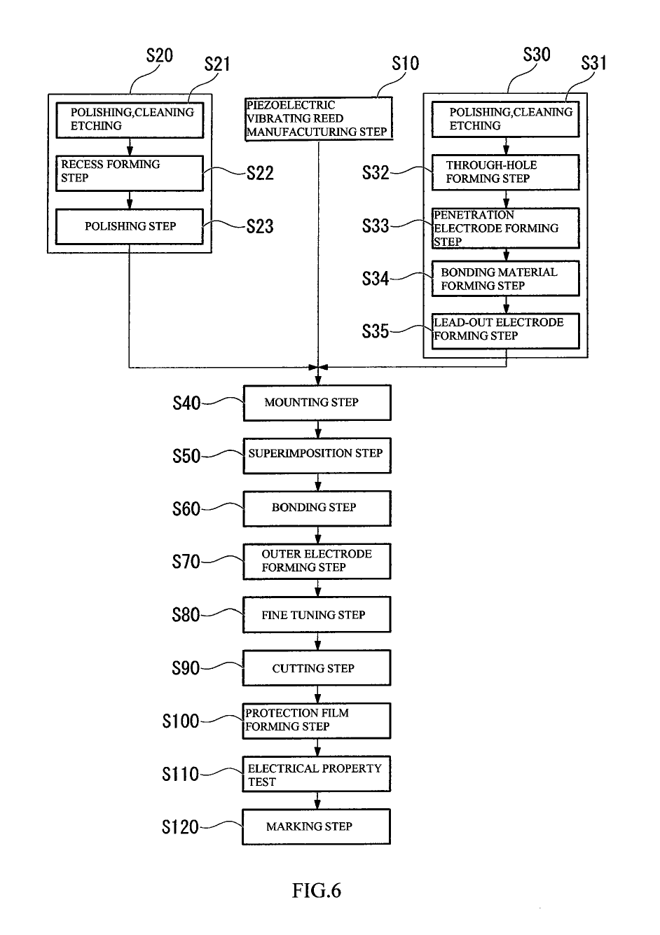

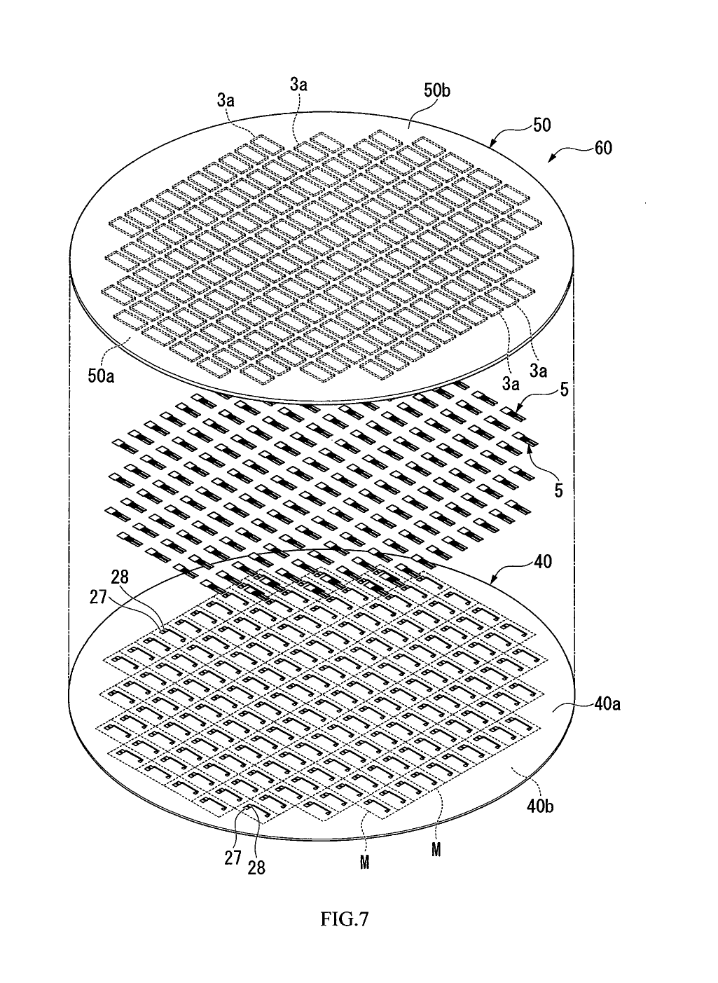

Next, the manufacturing method of the piezoelectric vibrator will be described. FIG. 6 is a flowchart of the manufacturing method of the piezoelectric vibrator according to the present embodiment. FIG. 7 is an exploded perspective view of a wafer assembly. In the following description, a method of manufacturing a plurality of piezoelectric vibrators (assembled fragments) 1 at a time by enclosing a plurality of piezoelectric vibrating reeds 5 between a base substrate wafer (first wafer) 40 including a plurality of base substrates 2 and a lid substrate wafer (second wafer) 50 including a plurality of 11d substrates 3 to form a wafer assembly 60 and cutting the wafer assembly (assembled body) 60 will be described. The dotted line M shown in the respective figures starting with FIG. 7 is a cutting line along which a cutting step performed later is achieved.

The manufacturing method of the piezoelectric vibrator according to the present embodiment mainly includes a piezoelectric vibrating reed manufacturing step (S10), a lid substrate wafer manufacturing step (S20), a base substrate wafer manufacturing step (S30), and an assembling step (S40 and subsequent steps). Among the steps, the piezoelectric vibrating reed manufacturing step (S10), the lid substrate wafer manufacturing step (S20), and the base substrate wafer manufacturing step (S30) can be performed in parallel.

First, as shown in FIG. 6, a piezoelectric vibrating reed manufacturing step is performed to manufacture the piezoelectric vibrating reed 5 shown in FIGS. 1 to 5 (S10). Moreover, after the piezoelectric vibrating reed 5 is manufactured, rough tuning of a resonance frequency is performed. Fine tuning of adjusting the resonance frequency more accurately is performed after a mounting step is performed.

### Lid Substrate Wafer Manufacturing Step

Subsequently, as shown in FIGS. 6 and 7, a lid substrate wafer manufacturing step is performed in which a lid substrate wafer 50 later serving as the lid substrate 3 is manufactured up to a stage immediately before anodic bonding is achieved (S20). Specifically, a disk-shaped lid substrate wafer 50 is formed by polishing a soda-lime glass to a predetermined thickness, cleaning the polished glass, and removing the affected uppermost layer by etching or the like (S21). After that, a recess forming step is performed in which a plurality of recess portions 3a to be used as a cavity C is formed in a matrix form on the rear surface 50a (the lower surface in FIG. 7) of the lid substrate wafer 50 by etching or the like (S22).

Subsequently, in order to secure airtightness between the lid substrate wafer 50 and a base substrate wafer 40 described later, a polishing step (S23) is performed in which at least the rear surface 50a of the lid substrate wafer 50 serving as the bonding surface to be bonded to the base substrate wafer 40 is polished so that the rear surface 50a has a mirror-like surface. In this way, the lid substrate wafer manufacturing step (S20) ends.

### Base Substrate Wafer Manufacturing Step

Subsequently, at the same or a different time as the lid substrate wafer manufacturing step, a base substrate wafer manufacturing step is performed in which a base substrate wafer 40 later serving as the base substrate 2 is manufactured up to a stage immediately before anodic bonding is achieved (S30). First, a disk-shaped base substrate wafer 40 is formed by polishing a soda-lime glass to a predetermined thickness, cleaning the polished glass, and removing the affected uppermost layer by etching or the like (S31). After that, a through-hole forming step is performed in which a plurality of through-holes 21 and 22 for disposing a pair of penetration electrodes 8 and 9 on the base substrate wafer is formed, for example, by press working or the like (S32). Specifically, the through-holes 21 and 22 can be formed by forming recess portions on the rear surface 40b of the base substrate wafer 40 by press working or the like and then polishing at least the front surface 40a of the base substrate wafer 40 so as to penetrate through the recess portions.

Subsequently, a penetration electrode forming step (S33) is performed in which penetration electrodes 8 and 9 are formed in the through-holes 21 and 22 formed during the through-hole forming step (S32). By doing so, in the through-holes 21 and 22, the core portions 31 are maintained to be even with both surfaces 40a and 40b (the upper and lower surfaces in FIG. 7) of the base substrate wafer 40. In this way, the penetration electrodes 8 and 9 can be formed.

Subsequently, a bonding material forming step is performed in which a conductive material is patterned on the front surface 40a of the base substrate wafer 40 so as to form a bonding material 23 (S34), and a lead-out electrode forming step is performed (S35). The bonding material 23 is formed on a region of the base substrate wafer 40 other than the formation region of the cavity C, namely the entire bonding region of the base substrate wafer 40 to be bonded to the rear surface 50a of the lid substrate wafer 50. In this way, the base substrate wafer manufacturing step (S30) ends.

Subsequently, the piezoelectric vibrating reed 5 manufactured by the piezoelectric vibrating reed manufacturing step (S10) is mounted on the lead-out electrodes 27 and 28 of the base substrate wafer 40 manufactured by the base substrate wafer manufacturing step (S30) with bumps B made of gold or the like disposed therebetween (S40). Then, a superimposition step is performed in which the base substrate wafer 40 and the lid substrate wafer 50 manufactured by the manufacturing steps of the respective wafers 40 and 50 are superimposed on each other (S50). Specifically, the two wafers 40 and 50 are aligned at a correct position using reference marks or the like not shown in the figure as indices. In this way, the mounted piezoelectric vibrating reed 5 is accommodated in the cavity C surrounded by the recess portion 3a formed on the lid substrate wafer 50 and the base substrate wafer 40.

After the superimposition step is performed, a bonding step is performed in which anodic bonding is achieved under a predetermined temperature atmosphere with application of a predetermined voltage in a state where the two superimposed wafers 40 and 50 are inserted into an anodic bonding machine not shown and the outer peripheral portions of the wafers are clamped by a holding mechanism not shown (S60). Specifically, a predetermined voltage is applied between the bonding material 23 and the lid substrate wafer 50. Then, an electrochemical reaction occurs at an interface between the bonding material 23 and the lid substrate wafer 50, whereby they are closely adhered tightly and anodically bonded. In this way, the piezoelectric vibrating reed 5 can be sealed in the cavity C, and a wafer assembly 60 can be obtained in which the base substrate wafer 40 and the lid substrate wafer 50 are bonded to each other. According to the present embodiment, by anodically bonding the two wafers 40 and 50, compared to the case of bonding the two wafers 40 and 50 by an adhesive or the like, it is possible to prevent positional shift due to aging or impact and warping of the wafer assembly 60 and to bond the two wafers 40 and 50 more tightly. In this case, in the present embodiment, since Al having a relatively low resistance is used for the bonding material 23, it is possible to apply a uniform voltage to the entire surface of the bonding material 23 and to easily form the wafer assembly 60 in which the bonding surfaces of the two wafers 40 and 50 are tightly anodically bonded to each other. Moreover, since the anodic bonding can be achieved with a relatively low voltage, it is possible to decrease energy consumption and to reduce manufacturing costs.

After that, a pair of outer electrodes 6 and 7 is formed so as to be electrically connected to the pair of penetration electrodes 8 and 9 (S70), and the frequency of the piezoelectric vibrator 1 is finely tuned (S80).

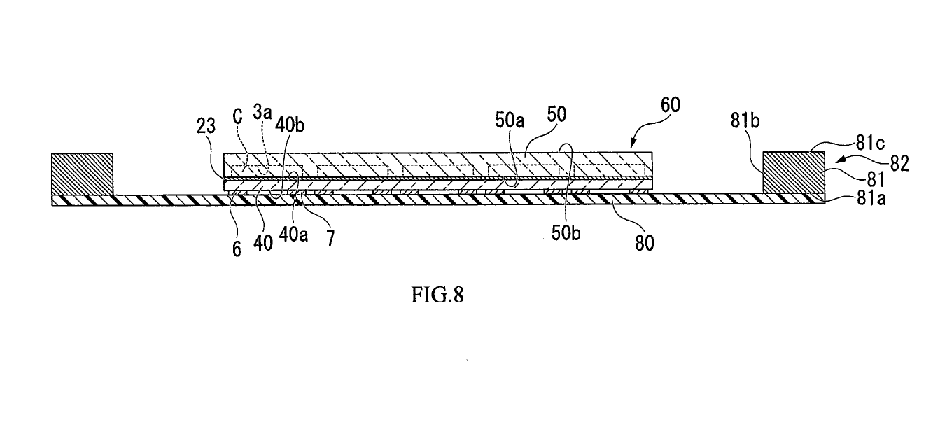

FIGS. 8 to 12 are sectional views illustrating the fragmentation step, showing a state where the wafer assembly is held on the magazine.

After the fine tuning of the frequency is completed, a fragmentation step is performed in which the bonded wafer assembly 60 is cut into small fragments (S90). In the fragmentation step (S90), as shown in FIG. 8, first, the wafer assembly 60 is held by a magazine 82 which includes a UV tape 80 and a ring frame 81. The ring frame 81 is a ring-shaped member whose inner diameter is larger than the diameter of the wafer assembly 60 and has the same thickness (the length in the axial direction thereof) as the wafer assembly 60. Moreover, the UV tape 80 is a polyolefin sheet coated with UV-curable resin, for example acrylic adhesive.

The magazine 82 can be produced by attaching the UV tape 80 on one surface 81a of the ring frame 81 so as to block a penetration hole 81b. The wafer assembly 60 is attached to an adhesion surface of the UV tape 80 in a state where the central axis of the ring frame 81 is identical to the central axis of the wafer assembly 60. Specifically, the rear surface 40b side (the outer electrodes 6 and 7 side) of the base substrate wafer 40 is attached to the adhesion surface of the UV tape 80. In this way, the wafer assembly 60 is set within the penetration hole 81b of the ring frame 81.

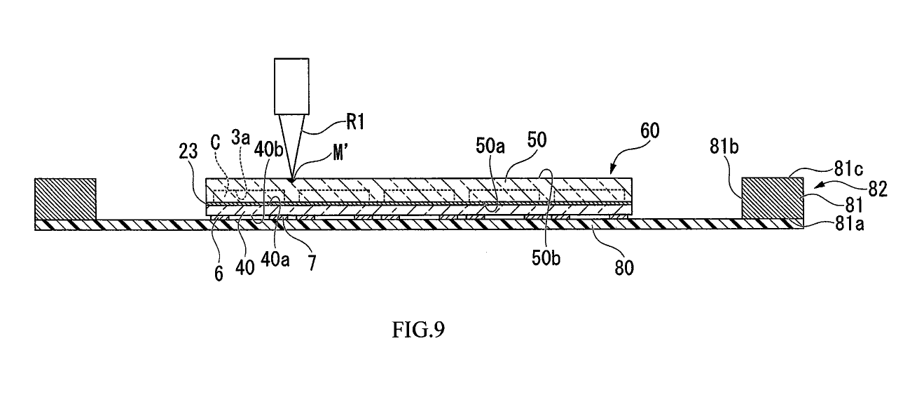

Subsequently, as shown in FIG. 9, a surface layer portion of the front surface 50b of the lid substrate wafer 50 is irradiated with a laser beam R1 along the cutting line M to form a scribe line M′ on the wafer assembly 60.

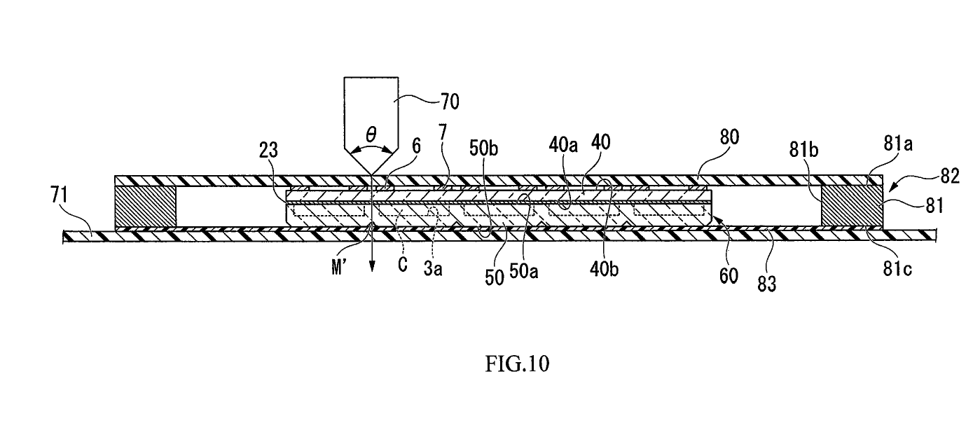

Subsequently, a cutting step is performed in which the wafer assembly 60 on which the scribe line M′ is formed is cut into individual piezoelectric vibrators 1. In the cutting step, first, as shown in FIG. 10, a separator 83 for protecting the lid substrate wafer 50 is attached to the other surface 81c of the ring frame 81 so as to block the penetration hole 81b. In this way, the wafer assembly 60 is held within the penetration hole 81b of the ring frame 81 in a state of being sandwiched between the UV tape 80 and the separator 83. In this state, the wafer assembly 60 is transferred to a breaking machine. In FIG. 10, reference numeral 71 is a silicon rubber disposed on the stage of the breaking machine.

Subsequently, a breaking step is performed in which a breaking stress is applied to the wafer assembly 60 transferred to the breaking machine. In the breaking step, a cutting blade 70 whose blade length is larger than the diameter of the wafer assembly 60 and whose blade edge angle θ is 80° to 100°, for example, is prepared. Then, the cutting blade 70 is positioned on the scribe line M′ from the side of the rear surface 40b of the base substrate wafer 40, and the blade edge of the cutting blade 70 is brought into contact with the rear surface 40b of the base substrate wafer 40. After that, a predetermined breaking stress (for example, 10 kg/inch) is applied to the wafer assembly 60 along the thickness direction (cutting line M) of the wafer assembly 60.

In this way, a crack is formed on the wafer assembly 60 along the thickness direction, and the wafer assembly 60 is cut in such a way that it is divided along the scribe line M′ formed on the lid substrate wafer 50. By pressing the cutting blade 70 on each scribe line M′, it is possible to divide the wafer assembly 60 into packages 10 for each cutting line M at once. After that, the separator 83 attached to the wafer assembly 60 is detached.

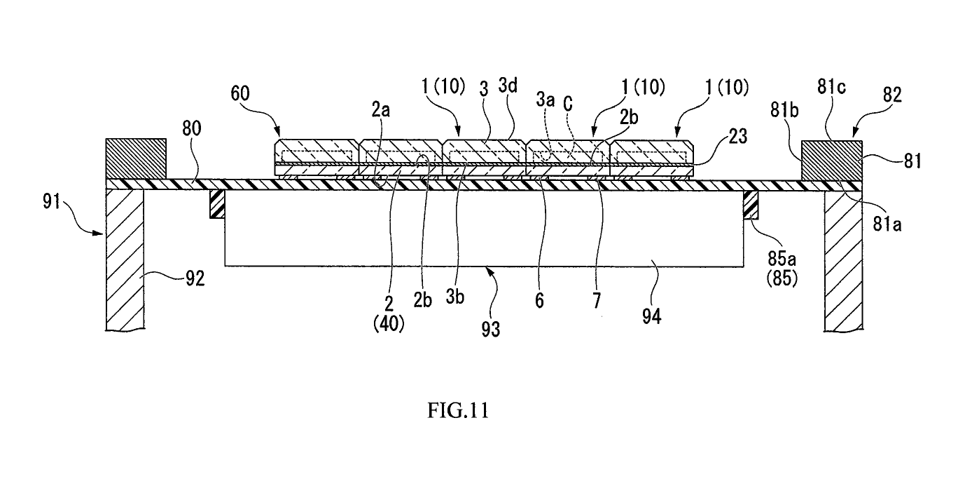

Subsequently, as shown in FIG. 11, the wafer assembly 60 is transferred to an expanding machine 91, and an expanding step of expanding the UV tape 80 is performed.

First, the expanding machine 91 will be described. The expanding machine 91 includes an annular base ring 92 on which the ring frame 81 is set, and a disk-shaped heater panel 93 which is disposed at an inner side of the base ring 92 and has a larger diameter than the wafer assembly 60. The heater panel 93 is configured by a base plate 94 on which the wafer assembly 60 is set, and a heat-transfer heater (not shown) mounted on the base plate 94, and is disposed such that the central axis of the heater panel 93 is identical to the central axis of the base ring 92. In addition, the heater panel 93 is configured to be movable along the axial direction by a drive means not shown. Although not shown in the figure, the expanding machine 91 is also provided with a pressing member that clamps the ring frame 81 set on the base ring 92 between the base ring 92 and the pressing member.

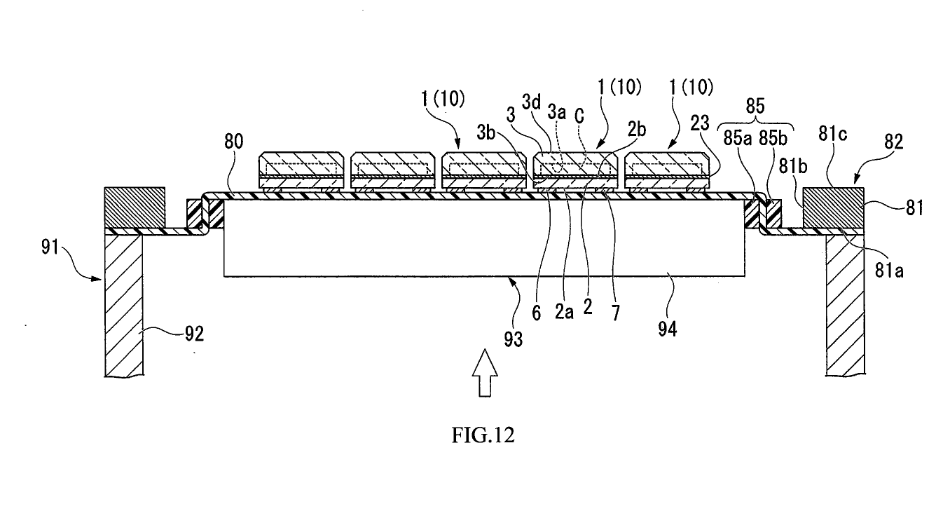

When the expanding step is performed using such a machine, first, an inner ring 85a of a grip ring 85 described later is set at an outer side of the heater panel 93 before the wafer assembly 60 is set on the expanding machine 91. At that time, the inner ring 85a is fixed to the heater panel 93 and set so as to be moved together when the heater panel 93 is moved. The grip ring 85 is a ring made of resin whose inner diameter is larger than the outer diameter of the heater panel 93 and smaller than the inner diameter of the penetration hole 81b of the ring frame 81. The grip ring 85 is configured by the inner ring 85a and an outer ring 85b (see FIG. 12) whose inner diameter is the same as the outer diameter of the inner ring 85a. That is, the inner ring 85a is stuck at the inner side of the outer ring 85b.

After that, the wafer assembly 60 fixed to the magazine 82 is set on the expanding machine 91. At that time, the wafer assembly 60 is set with the side of the UV tape 80 (the side of the outer electrodes 6 and 7) facing the heater panel 93 and the base ring 92. Moreover, the ring frame 81 is clamped between the base ring 92 and the pressing member not shown. Subsequently, the UV tape 80 is heated by the heater of the heater panel 93 so as to soften the UV tape 80. Moreover, as shown in FIG. 12, the heater panel 93 is raised together with the inner ring 85a (see the arrow in FIG. 12) with the UV tape 80 heated. At that time, since the ring frame 81 is clamped between the base ring 92 and the pressing member, the UV tape 80 is expanded toward the outer side in the diameter direction of the wafer assembly 60. By doing so, the packages 10 attached to the UV tape 80 are separated, and the space between the adjacent packages 10 increases. In this state, the outer ring 85b is set at the outer side of the inner ring 85a. Specifically, the inner ring 85a and the outer ring 85b are fitted to each other with the UV tape 80 interposed therebetween. In this way, the UV tape 80 in the expanded state is held on the grip ring 85. Moreover, the UV tape 80 at the outer side of the grip ring 85 is cut, and the ring frame 81 and the grip ring 85 are divided.

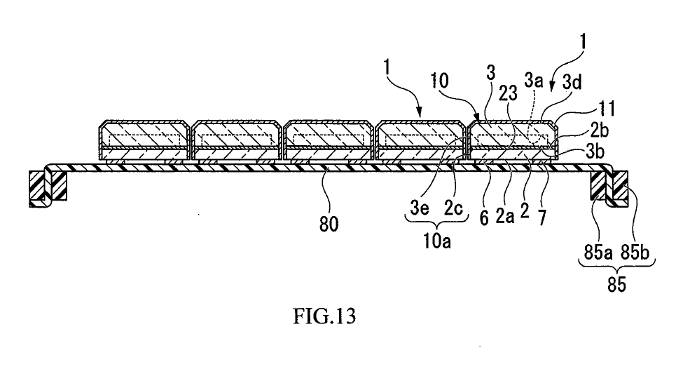

FIG. 13 is a sectional view illustrating a protection film forming step, showing a state where a plurality of piezoelectric vibrators is attached to the UV tape.

Subsequently, as shown in FIG. 13, a protection film forming step (S100) is performed in which the package 10 is coated with the protection film 11. Specifically, first, a plurality of packages 10 is transferred to a chamber of a sputtering machine with the UV tape 80 attached to the packages, and set so that the lid substrate 3 faces the film forming material (target) of the protection film 11. By performing sputtering in this state, atoms flying out from the film forming material are adhered onto the front surface 3d of the lid substrate 3 and the side surfaces 10a of the package 10. In this way, the protection film 11 is formed over the entire area including the front surface 3d of the lid substrate 3 and the side surfaces 10a of the package 10.

In this case, since the bonding material 23 is exposed to the side surfaces 10a of the package 10, in order to form the protection film 11 so as to cover the bonding material 23, it is necessary to dispose all packages 10 to be spaced from each other so that the side surfaces 10a are exposed.

According to the present embodiment, since the protection film forming step is performed in a state where the plurality of packages 10 are separated from each other in the expanding step, it is not necessary to disposed all packages 10 again so as to be spaced from each other, and thus, manufacturing efficiency can be improved. That is, since the protection film 11 can be formed in a state where a space is secured between the respective packages 10, it is possible to form the protection film 11 in a uniform manner with respect to the bonding material 23 exposed between the base substrate 2 and the lid substrate 3 in the respective packages 10.

Moreover, by performing sputtering in a state where the plurality of packages 10 is attached to the expanded UV tape 80, the protection film 11 can be formed at a time with respect to the plurality of fragmented packages 10. Therefore, it is possible to improve manufacturing efficiency as compared to the case of forming the protection films 11 on the packages 10 one by one. Moreover, it is possible to suppress the movement of the packages 10 at the time of transferring to the sputtering machine or deposition.

Furthermore, by performing sputtering from the side of the lid substrate 3 in a state where the UV tape 80 is attached to the rear surface 2a side of the base substrate 2, it is possible to suppress the film forming material from being scattered to adhere onto the rear surface 2a side of the base substrate 2. Therefore, since it is possible to suppress the film forming material from being adhered to the outer electrodes 6 and 7, the respective outer electrodes 6 and 7 are suppressed from being bridged by the protection film 11. In this way, even when a conductive metal material such as Cr is used for the protection film 11, it is possible to suppress the short-circuiting of the outer electrodes 6 and 7. Moreover, in the present embodiment, since the side surfaces of the outer electrodes 6 and 7 are positioned on the inner side than the side surfaces 2c of the base substrate 2, the peripheral edge of the protection film 11 and the outer electrodes 6 and 7 are disposed so as to be separated with a gap 12 therebetween (see FIG. 2). Therefore, even when a small amount of the film forming material is scattered to adhere onto the rear surface 2a side of the base substrate 2, it is possible to prevent the protection film 11 and the outer electrodes 6 and 7 from being connected and bridged.

In the present embodiment, since the film forming material is disposed to as to face the front surface 3d of the lid substrate 3, the film forming material can adhere to the front surface 3d of the lid substrate 3 more easily than the side surfaces 10a of the package 10. Specifically, the ratio of deposition rate of the front surface 3d of the lid substrate 3 to the side surface 10a of the package 10 is about 3:1 to 4:1. In order to decrease the ratio of deposition rate, it is preferable to perform sputtering while causing the grip ring 85 (the package 10) to rotate.

Subsequently, a pickup step is performed so as to pick up the piezoelectric vibrators 1 on which the protection film 11 is formed. In the pickup step, first, a UV beam is irradiated onto the UV tape 80 so as to decrease the adhesion force of the UV tape 80. In this way, the piezoelectric vibrators 1 are separated from the UV tape 80. Thereafter, the piezoelectric vibrators 1 are suctioned by a nozzle or the like while detecting the positions thereof through image recognition or the like, whereby the piezoelectric vibrators 1 separated from the UV tape 80 are picked up.

In this way, a plurality of two-layered surface mounted device-type piezoelectric vibrators 1 shown in FIG. 1, in which the piezoelectric vibrating reed 5 is sealed in the cavity C formed between the base substrate 2 and the lid substrate 3 being anodically bonded together, can be manufactured at a time.

Subsequently, an inner electrical property test is conducted (S110). That is, the resonance frequency, resonance resistance value, drive level properties (the excitation power dependence of the resonance frequency and the resonance resistance value), and the like of the piezoelectric vibrating reed 5 are measured and checked. Moreover, the insulation resistance value properties and the like are checked as well. Finally, an external appearance test of the piezoelectric vibrator 1 is conducted to check the dimensions, the quality, and the like.

FIG. 14 is a perspective view illustrating a marking step, showing an external appearance of the piezoelectric vibrator corresponding to FIG. 1.

A marking 13 is printed on the piezoelectric vibrators 1 for which the electrical property test and the external appearance test have been completed, and which passed the tests (S120). As shown in FIG. 14, the marking 13 is printed by irradiating a laser beam R2 from the vertical direction to the front surface 3d of the lid substrate 3 to remove the protection film 11 on the front surface 3d of the lid substrate 3, whereby a product type, a product number, the date of manufacturing, and the like are printed. In this way, by removing the protection film 11 to print the marking 13, since it is not necessary to form an additional plating film or the like in order to print the marking 13, it is possible to improve manufacturing efficiency.

In the marking step (S120), it is preferable to adjust the power of the laser beam R2 so that the laser beam penetrates through only the protection film 11. In this way, it is possible to suppress the laser beam R2 from passing through the base substrate 2 to reach the inner side of the cavity C. That is, since the laser beam R2 is suppressed from being irradiated onto the piezoelectric vibrating reeds 5 to suppress damages to the piezoelectric vibrating reeds 5, it is possible to suppress the laser beam from affecting the electrical properties (frequency characteristics) of the piezoelectric vibrating reeds 5.

Moreover, in order to reliably suppress the laser beam R2 from passing through the base substrate 2, it is preferable to use a laser having a high absorption to a glass material. As such a laser, a CO₂ laser having a wavelength of 10.6 μm, a fourth harmonic laser having a wavelength of 266 nm, and the like can be used, for example. Among these lasers, the use of a CO₂ laser having a relatively long wavelength enables suppressing damage to the base substrate 2 in a more reliable manner.

As described above, in the present embodiment, on the outer surface of the package 10, the bonding material 23 is coated by the protection film 11 having higher resistance to corrosion than the bonding material 23.

According to this configuration, since the bonding material 23 is covered by the protection film 11, the bonding material 23 will not be exposed to the outside. Therefore, it is possible to suppress the bonding material 23 from coming into contact with the air and to suppress corrosion of the bonding material 23 due to moisture or the like in the air. In this case, since the protection film 11 is formed of a material having higher resistance to corrosion than the bonding material 23, it is possible to suppress the bonding material 23 from being exposed to the outside due to corrosion of the protection film 11 and to reliably suppress corrosion of the bonding material 23. Therefore, it is possible to maintain the airtightness of the cavity C in a stable state for a long period and to provide the piezoelectric vibrator 1 having excellent vibration characteristics and high reliability.

### Oscillator

Next, an oscillator according to another embodiment of the invention will be described with reference to FIG. 15.

In an oscillator 100 according to the present embodiment, the piezoelectric vibrator 1 is used as an oscillating piece electrically connected to an integrated circuit 101, as shown in FIG. 15. The oscillator 100 includes a substrate 103 on which an electronic component 102, such as a capacitor, is mounted. The integrated circuit 101 for an oscillator is mounted on the substrate 103, and the piezoelectric vibrator 1 is mounted near the integrated circuit 101. The electronic component 102, the integrated circuit 101, and the piezoelectric vibrator 1 are electrically connected to each other by a wiring pattern (not shown). In addition, each of the constituent components is molded with a resin (not shown).

In the oscillator 100 configured as described above, when a voltage is applied to the piezoelectric vibrator 1, the piezoelectric vibrating reed 5 in the piezoelectric vibrator 1 vibrates. This vibration is converted into an electrical signal due to the piezoelectric property of the piezoelectric vibrating reed 5 and is then input to the integrated circuit 101 as the electrical signal. The input electrical signal is subjected to various kinds of processing by the integrated circuit 101 and is then output as a frequency signal. In this way, the piezoelectric vibrator 1 functions as an oscillating piece.

Moreover, by selectively setting the configuration of the integrated circuit 101, for example, an RTC (real time clock) module, according to the demands, it is possible to add a function of controlling the operation date or time of the corresponding device or an external device or of providing the time or calendar in addition to a single functional oscillator for a timepiece.

As described above, since the oscillator 100 according to the present embodiment includes the piezoelectric vibrator 1 capable of securing the airtightness of the cavity C, the high-quality oscillator 100 having excellent characteristics and reliability can be provided. In addition to this, it is possible to obtain a highly accurate frequency signal which is stable over a long period of time.

### Electronic Apparatus

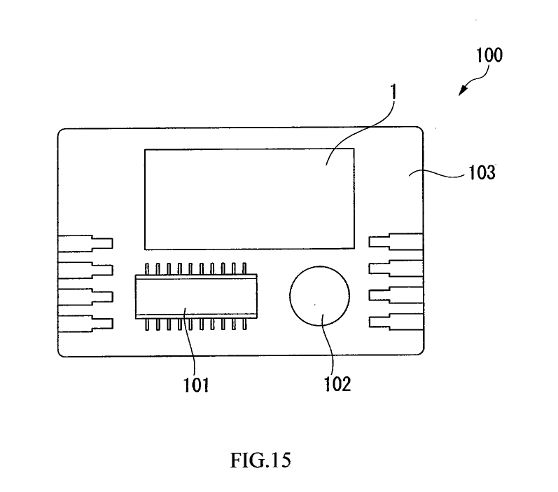

Next, an electronic apparatus according to another embodiment of the invention will be described with reference to FIG. 16. In addition, a portable information device 110 including the piezoelectric vibrator 1 will be described as an example of an electronic apparatus.

The portable information device 110 according to the present embodiment is represented by a mobile phone, for example, and has been developed and improved from a wristwatch in the related art. The portable information device 110 is similar to a wristwatch in external appearance, and a liquid crystal display is disposed in a portion equivalent to a dial pad so that a current time and the like can be displayed on this screen. Moreover, when it is used as a communication apparatus, it is possible to remove it from the wrist and to perform the same communication as a mobile phone in the related art with a speaker and a microphone built in an inner portion of the band. However, the portable information device 110 is very small and light compared with a mobile phone in the related art.

Next, the configuration of the portable information device 110 according to the present embodiment will be described. As shown in FIG. 16, the portable information device 110 includes the piezoelectric vibrator 1 and a power supply section 111 for supplying power. The power supply section 111 is formed of a lithium secondary battery, for example. A control section 112 which performs various kinds of control, a clock section 113 which performs counting of time and the like, a communication section 114 which performs communication with the outside, a display section 115 which displays various kinds of information, and a voltage detecting section 116 which detects the voltage of each functional section are connected in parallel to the power supply section 111. In addition, the power supply section 111 supplies power to each functional section.

The control section 112 controls an operation of the entire system. For example, the control section 112 controls each functional section to transmit and receive the audio data or to measure or display a current time. In addition, the control section 112 includes a ROM in which a program is written in advance, a CPU which reads and executes a program written in the ROM, a RAM used as a work area of the CPU, and the like.

The clock section 113 includes an integrated circuit, which has an oscillation circuit, a register circuit, a counter circuit, and an interface circuit therein, and the piezoelectric vibrator 1. When a voltage is applied to the piezoelectric vibrator 1, the piezoelectric vibrating reed 5 vibrates, and this vibration is converted into an electrical signal due to the piezoelectric property of crystal and is then input to the oscillation circuit as the electrical signal. The output of the oscillation circuit is binarized to be counted by the register circuit and the counter circuit. Then, a signal is transmitted to or received from the control section 112 through the interface circuit, and current time, current date, calendar information, and the like are displayed on the display section 115.

The communication section 114 has the same function as a mobile phone in the related art, and includes a wireless section 117, an audio processing section 118, a switching section 119, an amplifier section 120, an audio input/output section 121, a telephone number input section 122, a ring tone generating section 123, and a call control memory section 124.

The wireless section 117 transmits/receives various kinds of data, such as audio data, to/from the base station through an antenna 125. The audio processing section 118 encodes and decodes an audio signal input from the wireless section 117 or the amplifier section 120. The amplifier section 120 amplifies a signal input from the audio processing section 118 or the audio input/output section 121 up to a predetermined level. The audio input/output section 121 is formed by a speaker, a microphone, and the like, and amplifies a ring tone or incoming sound loudly or collects the sound.

In addition, the ring tone generating section 123 generates a ring tone in response to a call from the base station. The switching section 119 switches the amplifier section 120, which is connected to the audio processing section 118, to the ring tone generating section 123 only when a call arrives, so that the ring tone generated in the ring tone generating section 123 is output to the audio input/output section 121 through the amplifier section 120.

In addition, the call control memory section 124 stores a program related to incoming and outgoing call control for communications. Moreover, the telephone number input section 122 includes, for example, numeric keys from 0 to 9 and other keys. The user inputs a telephone number of a communication destination by pressing these numeric keys and the like.

The voltage detecting section 116 detects a voltage drop when a voltage, which is applied from the power supply section 111 to each functional section, such as the control section 112, drops below the predetermined value, and notifies the control section 112 of the detection. In this case, the predetermined voltage value is a value which is set beforehand as the lowest voltage necessary to operate the communication section 114 stably. For example, it is about 3 V. When the voltage drop is notified from the voltage detecting section 116, the control section 112 disables the operation of the wireless section 117, the audio processing section 118, the switching section 119, and the ring tone generating section 123. In particular, the operation of the wireless section 117 that consumes a large amount of power should be necessarily stopped. In addition, a message informing that the communication section 114 is not available due to insufficient battery power is displayed on the display section 115.

That is, it is possible to disable the operation of the communication section 114 and display the notice on the display section 115 by the voltage detecting section 116 and the control section 112. This message may be a character message. Or as a more intuitive indication, a cross mark (X) may be displayed on a telephone icon displayed at the top of the display screen of the display section 115.

In addition, the function of the communication section 114 can be more reliably stopped by providing a power shutdown section 126 capable of selectively shutting down the power of a section related to the function of the communication section 114.

As described above, since the portable information device 110 according to the present embodiment includes the piezoelectric vibrator 1 capable of securing the airtightness of the cavity C, the high-quality portable information device 110 having excellent characteristics and reliability can be provided. In addition to this, it is possible to display highly accurate clock information which is stable over a long period of time.

### Radio-Controlled Timepiece

Next, a radio-controlled timepiece according to still another embodiment of the invention will be described with reference to FIG. 17.

As shown in FIG. 17, a radio-controlled timepiece 130 according to the present embodiment includes the piezoelectric vibrators 1 electrically connected to a filter section 131. The radio-controlled timepiece 130 is a timepiece with a function of receiving a standard radio wave including the clock information, automatically changing it to the correct time, and displaying the correct time.

In Japan, there are transmission centers (transmission stations) that transmit a standard radio wave in Fukushima Prefecture (40 kHz) and Saga Prefecture (60 kHz), and each center transmits the standard radio wave. A long wave with a frequency of, for example, 40 kHz or 60 kHz has both a characteristic of propagating along the land surface and a characteristic of propagating while being reflected between the ionospheric layer and the land surface, and therefore has a propagation range wide enough to cover the entire area of Japan through the two transmission centers.

Hereinafter, the functional configuration of the radio-controlled timepiece 130 will be described in detail.

An antenna 132 receives a long standard radio wave with a frequency of 40 kHz or 60 kHz. The long standard radio wave is obtained by performing AM modulation of the time information, which is called a time code, using a carrier wave with a frequency of 40 kHz or 60 kHz. The received long standard wave is amplified by an amplifier 133 and is then filtered and synchronized by the filter section 131 having the plurality of piezoelectric vibrators 1. In the present embodiment, the piezoelectric vibrators 1 include crystal vibrator sections 138 and 139 having resonance frequencies of 40 kHz and 60 kHz, respectively, which are the same frequencies as the carrier frequency.

In addition, the filtered signal with a predetermined frequency is detected and demodulated by a detection and rectification circuit 134.

Then, the time code is extracted by a waveform shaping circuit 135 and counted by the CPU 136. The CPU 136 reads the information including the current year, the total number of days, the day of the week, the time, and the like. The read information is reflected on an RTC 138, and the correct time information is displayed.

Because the carrier wave is 40 kHz or 60 kHz, a vibrator having the tuning fork structure described above is suitable for the crystal vibrator sections 138 and 139.

Moreover, although the above explanation has been given for the case in Japan, the frequency of a long standard wave is different in other countries. For example, a standard wave of 77.5 kHz is used in Germany. Therefore, when the radio-controlled timepiece 130 which is also operable in other countries is assembled in a portable device, the piezoelectric vibrator 1 corresponding to frequencies different from the frequencies used in Japan is necessary.

As described above, since the radio-controlled timepiece 130 according to the present embodiment includes the piezoelectric vibrator 1 capable of securing the airtightness of the cavity C, the high-quality radio-controlled timepiece 130 having excellent characteristics and reliability can be provided. In addition to this, it is possible to count the time highly accurately and stably over a long period of time.

It should be noted that the technical scope of the present invention is not limited to the embodiments above, and the present invention can be modified in various ways without departing from the spirit of the present invention. That is, specific materials and layer structures exemplified in the embodiments are only examples and can be appropriately changed.

For example, in the embodiment described above, although the bonding material 23 is formed on the front surface 40a of the base substrate wafer 40, contrary to this, the bonding material 23 may be formed on the rear surface 50a of the lid substrate wafer 50. In this case, the bonding material 23 may be formed on only the bonding surface of the rear surface 50a of the lid substrate wafer 50 to be bonded to the base substrate wafer 40 by patterning after the film formation. However, by forming the bonding material 23 on the entire rear surface 50a including the inner surface of the recess portion 3a, the patterning of the bonding material 23 is not necessary, and thus, manufacturing costs can be decreased.

Moreover, in the embodiment described above, a configuration in which the protection film 11 is continuously formed over an area including the front surface 3d of the lid substrate 3 and the side surfaces 10a of the package 10 has been described. However, the present invention is not limited to this, and the protection film 11 may be formed so as to cover at least only the bonding material 23 exposed to the side surfaces of the package 10. Moreover, in the embodiment described above, the case where the protection film 11 is formed by a sputtering method has been described. However, the present invention is not limited to this, and the protection film 11 may be formed by various deposition methods such as a CVD method.

Furthermore, in the bonding step (S60) described above, a method (so-called counter electrode method) in which an auxiliary bonding material serving as an anode is disposed on the rear surface 40b of the base substrate wafer 40 and a cathode is disposed on the front surface 50b of the lid substrate wafer 50 may be used, and a method (so-called direct electrode method) in which the bonding material 23 is connected to an anode, a cathode is disposed on the front surface 50b of the lid substrate wafer 50, and a voltage is directly applied to the bonding material 23 may be used.

When the counter electrode method is used, by applying a voltage between the auxiliary bonding material and the cathode at the time of anodic bonding, an anodic bonding reaction occurs between the auxiliary bonding material and the rear surface 40b of the base substrate wafer 40, whereby the bonding material 23 and the rear surface 50a of the lid substrate wafer 50 are anodically bonded. In this way, it is possible to apply a voltage to the entire surface of the bonding material 23 in a more uniform manner and to make the bonding material 23 and the rear surface 50a of the lid substrate wafer 50 reliably anodically bonded.

In contrast, when the direct electrode method is used, since an auxiliary bonding material removal operation after the bonding step which is necessary in the counter electrode method is not necessary, it is possible to decrease the number of manufacturing steps and to improve manufacturing efficiency.

In the present embodiment, a piezoelectric vibrator was manufactured by sealing a piezoelectric vibrating reed in a package using the method of manufacturing a package according to the present invention. However, a device other than the piezoelectric vibrator may be manufactured by sealing an electronic component other than the piezoelectric vibrating reed in a package.

What is claimed is:

1. A method for producing piezoelectric vibrators each containing a piezoelectric vibrating strip inside, comprising:
(a) defining, along imaginary boundary lines, a plurality of first substrates on a first wafer and a plurality of second substrates on a second wafer;
(b) layering the first and second wafers such that at least some of the first substrates substantially coincide respectively with at least some of the corresponding second substrates, with a bonding film being placed between a respective at least some of the coinciding first and second substrates;
(c) hermetically bonding at least some of the coinciding first and second substrates which have the bonding film therebetween;
(d) cutting off each of at least some of packages formed of the hermetically bonded first and second substrates; and
(e) applying a protection film on a respective at least some of the cut-off packages such that the protection film covers at least the bonding film exposed from between the bonded first and second substrates.

2. The method according to claim 1, wherein cutting off each of at least some of packages comprises securing the second wafer of the layered first and second wafers on an adhesive sheet.

3. The method according to claim 2, wherein cutting off each of at least some of packages comprises scribing the first wafer with a laser to form grooves along the imaginary boundary lines.

4. The method according to claim 3, wherein cutting off each of at least some of packages comprises pressing a cutting blade along the boundary lines on the second wafer via the adhesive sheet.

5. The method according to claim 4, wherein pressing a cutting blade comprises pressing a cutting blade with a stress of about 10 kg/inch.

6. The method according to claim 4, wherein pressing a cutting blade comprises pressing a cutting blade having a blade edge angle ranging from 80° to 100°.

7. The method according to claim 4, wherein cutting off each of at least some of packages comprises expanding the adhesive sheet to separate the cut-off packages from one another.

8. The method according to claim 7, wherein applying a protection film on a respective at least some of the cut-off packages comprises applying a protection film by spattering on the at least some of the cut-off packages on the expanded adhesive sheet.

9. The method according to claim 1, wherein applying a protection film comprises applying a protection film over surfaces of the package except a bottom surface thereof.

10. The method according to claim 9, wherein the protection film applied to the top surface of the package has a thickness of about 1000 Å, and the protection film applied to the side surfaces has a thickness of about 300-400 Å.

11. The method according to claim 1, wherein applying a protection film comprises spinning the cut-off packages.

12. The method according to claim 1, wherein the protection film is made of either Si or Cr.

13. The method according to claim 1, further comprising marking the applied protection film.

14. A piezoelectric vibrator comprising:
a hermetically closed package comprising first and second substrates hermetically bonded together via a bonding film therebetween; and
a protection film covering at least the bonding film exposed from between the bonded first and second substrates.

15. The piezoelectric vibrator according to claim 14, wherein the protection film covers surfaces of the package except a bottom surface thereof.

16. The piezoelectric vibrator according to claim 15, wherein the protection film applied to the top surface of the package has a thickness of about 1000 Å, and the protection film applied to the side surfaces has a thickness of about 300-400 Å.

17. The piezoelectric vibrator according to claim 14, wherein the protection film is made of either Si or Cr.

18. An oscillator comprising the piezoelectric vibrator defined in claim 14.

19. An electronic device in which the piezoelectric vibrator defined in claim 14 is electrically connected to a clock.

20. An electronic device in which the piezoelectric vibrator defined in claim 14 is electrically connected to a filter.
